(19) United States
(12) Patent Application Publication
(10) Pub. No.: US 2010/0170438 A1
(43) Pub. Date: Jul. 8, 2010

(54) GAS DISTRIBUTOR COMPRISING A PLURALITY OF DIFFUSION-WELDED PANES AND A METHOD FOR THE PRODUCTION OF SUCH A GAS DISTRIBUTOR

(76) Inventors: Victor Saywell, Suffolk (GB); Chris Humby, Cambridgeshire (GB); Fred Crawley, Hertfordshire (GB)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(21) Appl. No.: 12/663,272

(22) PCT Filed: Jun. 4, 2008
(86) PCT No.: PCT/EP2008/056873

§ 371 Date: Dec. 4, 2009

(30) Foreign Application Priority Data
Jun. 6, 2007 (DE) 10 2007 026 349.1

(51) Int. Cl. C23C 16/455; B23K 20/00; B23K 31/02

(52) U.S. Cl. 118/715; 228/193; 228/176

(57) ABSTRACT

The invention relates to a gas distributor (1, 2) for a CVD reactor comprising two or more chambers (8, 9, 14), with supply lines ending therein, wherein at least one of the chambers (8, 9) forms a gas volume and is connected to gas outlet openings (23) associated with the bottom (2) of the gas distributor (1, 2) by means of a plurality of small tubes (11, 12, 13) crossing at least one other chamber (9, 14). For simplified production and technical enhancement, the gas distributor (1, 2), at least in the region of the small tubes (11, 12, 13), is made of a plurality of structured disks resting on top of each other, which are diffusion-welded to each other by pressure and temperature.

The invention relates to a gas distributor for a CVD reactor with two or more chambers, into each of which supply lines open out, at least one of the chambers defining a gas volume and being connected to gas outlet openings associated with the bottom of the gas distributor by means of a multiplicity of small tubes crossing at least one other chamber.

The invention also relates to a method for the production of a gas distributor of this kind.

EP 0 687 749 B1, DE 695 04 762 T2, U.S. Pat. No. 5,871,586 and US 2006/0021574 A1 disclose gas distributors of this kind, also known as “showerhead” distributors. They comprise plates lying in a horizontal direction, one above the other. The plates are spaced apart vertically from one another, respectively forming the floor and ceiling of a chamber. The peripheries of the chambers are formed by annular peripheral parts of steel. The downwardly facing bottom of the gas distributor has a multiplicity of gas outlet openings. The chamber lying above it is a cooling chamber, which is flowed through by a liquid coolant, for example water. Above this cooling chamber, there are two gas volumes, separated from one another in a gas-tight manner. Each of the gas volumes is connected to the bottom of the gas distributor by a multiplicity of up to more than 15,000 small tubes. The small tubes open out into the gas outlet openings and thereby cross at least the cooling chamber.

The production of gas distributors of this kind is laborious, since the small tubes have to be individually soldered into previously made holes. It is also disadvantageous that different materials are used, that is on the one hand the walls of the chambers and the small tubes consisting of stainless steel, and on the other hand, the solder.

DE 696 30 484 T2, EP 1 381 078 A1 and U.S. Pat. No. 6,444,042 B1 disclose gas inlet distributors which are formed in a sandwich-like manner from a multiplicity of disks, the individual disks being structured in order that a distribution of gas can take place within the plane of the disks. For this purpose, criss-crossing channels are provided. They thereby form block-like elevations, which have a central opening through which one gas can flow, and around which another gas can flow.

US 2002/0152960 A1 discloses a gas distributor which is likewise of a sandwich-like construction. There, a lower disk and an upper disk respectively have a cutout on the broad side, formed by grooves that extend in the form of a grid, so that rectangular pedestals with a central opening remain. If these outer disks are placed one above the other with a correspondingly perforated inner disk interposed, this creates small tubes, each of which passes through a chamber.

US 2006/0201428 A1, U.S. Pat. No. 7,168,447 B2, U.S. Pat. No. 6,302,964 B1, US 2002/0005442 A1 and WO2006/040275 A1 likewise disclose gas distributors which comprise a number of disks lying one above the other. The broad side faces of the disks are provided with channels. In the assembled state, these channels are closed.

It is an object of the invention to provide a gas distributor that is easier to produce and is technically improved.

The object is achieved by the invention specified in the claims, where Claims 2 to 14 primarily concern advantageous developments of the gas distributor specified in Claim 1 but each claim represents an independent solution for achieving the object and can be combined with any other claim.

First and foremost, it is provided that the gas distributor comprises a multiplicity of structured disks lying one above the other, which are connected to one another and, in particular, are diffusion-welded to one another by pressure and temperature. In particular, the small tubes may be provided by a plurality of these disks. The small tubes are then defined by a multiplicity of annular disks lying one above the other, the annular disks lying substantially congruently one above the other. The small tubes are built up from these annular disks. The disks preferably consist of stainless steel and have, in the region of the free spaces or openings formed by them, the said annular disks, which are connected to one another by way of webs. In the welded state, the annular disks lying one above the other then form the small tubes, which cross the corresponding chamber. The chamber volume is formed by the intermediate spaces between the webs. In order to ensure improved flow through the chambers by the fluids associated with them, for example a gas or a liquid, the webs have a smaller material thickness than the disks themselves or the annular disks forming the small tubes. The material thickness of the disks may lie between 0.2 mm and 2 mm. The material thickness preferably lies in the range between 0.3 mm and 1 mm. With respect to the plane of extent of the individual disks, the webs have a material thickness which is less than the outside diameter of the annular disks. The annular disks may have a circular shape in outline. The outline of the annular disks may, however, also deviate from this. Measures are taken to make the webs that are preferably lying substantially congruently one above the other gas-permeable. The webs of disks connected to one another define gas-permeable walls. This can be achieved by the cross-sectional reduction already described above. However, it is also possible for disks of different web configuration to be disposed one above the other. The gas distributor according to the invention preferably comprises a multiplicity of differently configured disks, as is likewise the case in the prior art. However, it is provided according to the invention that each axial zone of the gas distributor is formed by a multiplicity of identically configured disks, which are merely placed one above the other for production, it being possible for differently configured disks to alternate with one another. The inside diameter of the small tubes, that is of the flow channels, may be 0.4 mm to 1 mm. The surface density of the small tubes or the surface density of the gas outlet openings may be between 10 and 20 per cm². With the method that is additionally claimed, the production of a gas distributor with a diameter of at least 180 mm is possible. The diameter may also be at least 380 mm or at least 500 mm. It is even possible to produce gas distributors with diameters of more than 700 mm. The gas distributor preferably has a total of two gas volumes. One of these gas volumes may be produced from a solid component. The other gas volume may be part of the diffusion-welded plate structure. The diffusion-welded plate structure may additionally also have the aforementioned cooling chamber, which is crossed by small tubes which connect the two gas volumes separately from one another to the gas outlet openings in the bottom of the gas distributor. In a further configuration of the invention, it is provided that plates on which the annular disks lie at the web midpoint of crossing webs and plates on which the annular disks lie on the crossing points of crossing webs alternate in the region of a chamber.

The invention also relates to a method for producing a gas distributor of this kind. The production method substantially relates to the plate structure of the gas distributor, which is formed by a multiplicity of structured disks of metal, preferably stainless steel. These are each formed by metal sheets. The metal sheets are first cut or punched to their outer shape. Then the disks are structured. If the disks are disposed between individual chambers, they merely have holes. The disks which form a chamber have a web structure, the webs connecting the annular disks to one another. This web structure may be produced by an etching process. For this purpose, the metal sheets cut to shape are first photolithographically masked. This involves first applying a photosensitive photoresist over a large area to the broad side face of the plate. After an exposure step, the non-exposed or exposed zones of the photoresist layer are removed again. After that, the zones freed of the photoresist are etched. An anisotropic etching process is preferably used. In a second etching process, in which merely the annular disk surfaces and the periphery are masked, the material thickness of the webs can be reduced. The plates structured in this way are placed one above the other in such a way that the annular disks make up small tubes and the chambers of broad side faces merely have holes. Finally, the stack of plates is pressed together in a furnace and brought to a temperature which lies somewhat below the melting temperature of the metal, in particular stainless steel. The stack of plates is exposed to this pressure and this temperature until the broad faces lying one above the other have intimately bonded to one another. In order to facilitate the identification of the individual plates, each plate has an identification tag in the form of a peripheral projection, on which an identification is provided. The plates, which are substantially circular in plan view, may additionally have alignment lugs that protrude from their periphery and have alignment openings. An alignment device may have a multiplicity of alignment pins, over which the alignment lugs can be placed in such a way that the alignment pins protrude through the alignment openings. This makes it possible for the structured disks to be placed exactly one above the other.

An exemplary embodiment of the invention is explained below on the basis of accompanying drawings, in which:

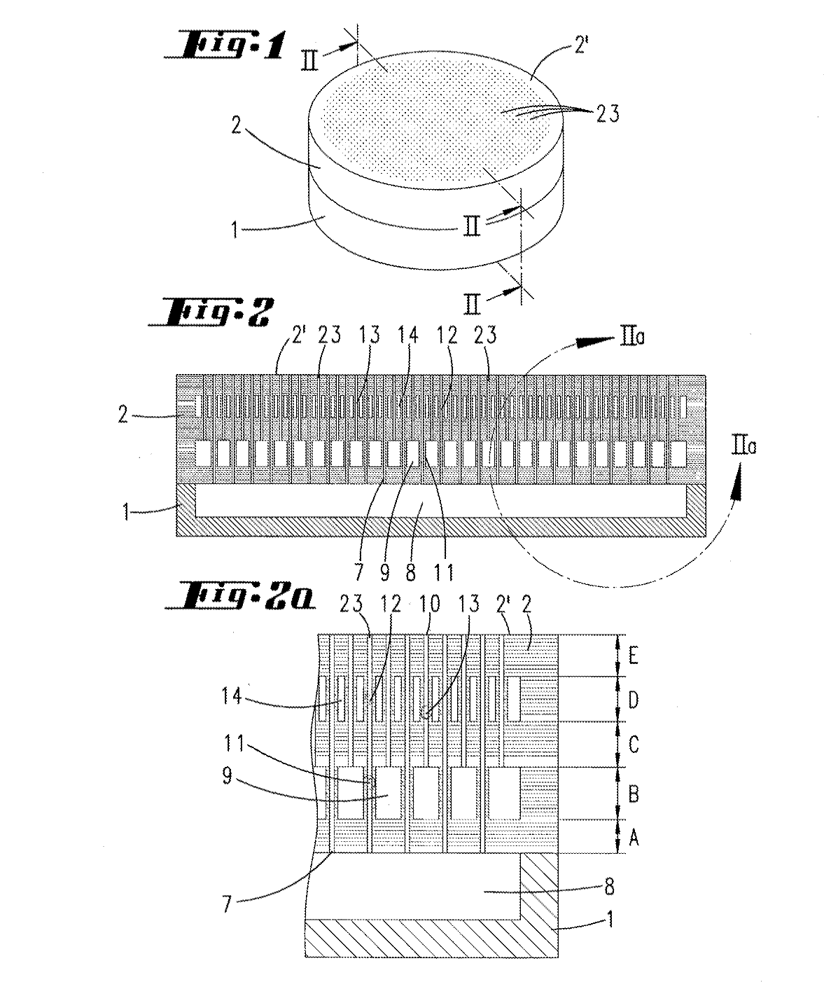

FIG. 1 shows an inverted gas distributor in a perspective representation;

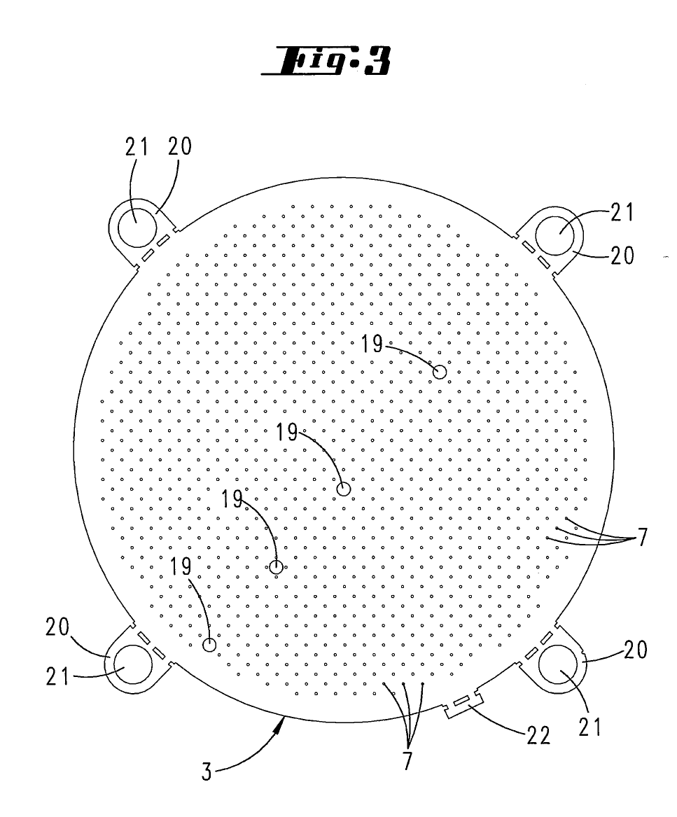

FIG. 2 shows a section according to the line II-II in FIG. 1, in which the zones A, B, C, D, E of the gas distributor are represented;

FIG. 2a shows an enlarged detail from FIG. 2;

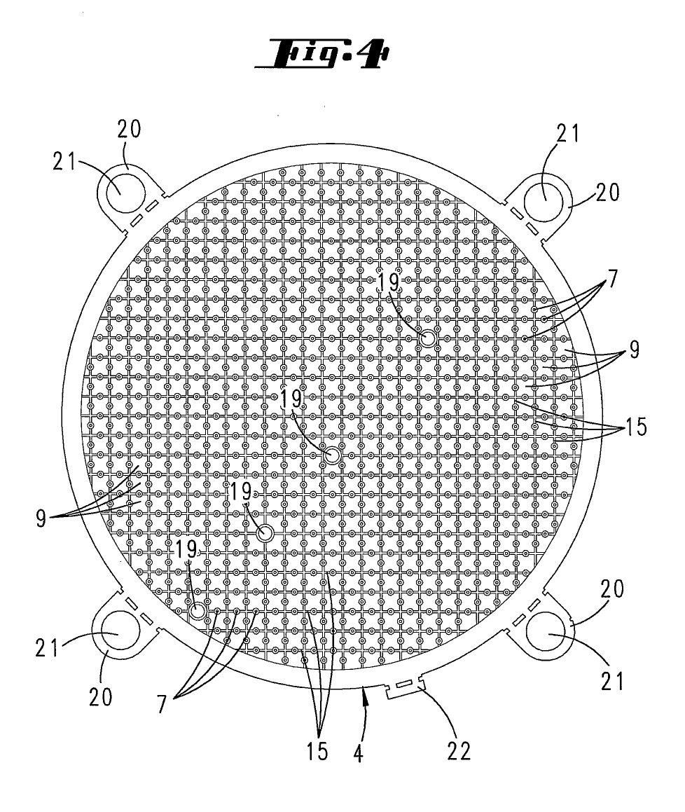

FIG. 3 shows a plan view of a disk 3, forming the zone A;

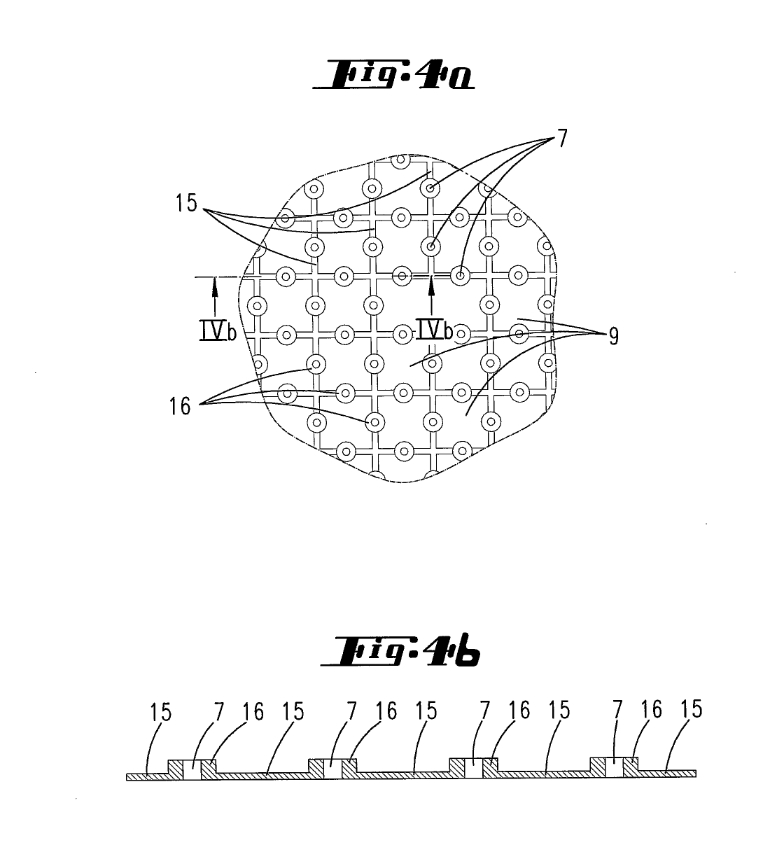

FIG. 4 shows a plan view of a first disk 4, forming the zone B;

FIG. 4a shows an enlarged detail from the grid structure of the disk 4;

FIG. 4b shows a section according to the line IVb-IVb in FIG. 4a;

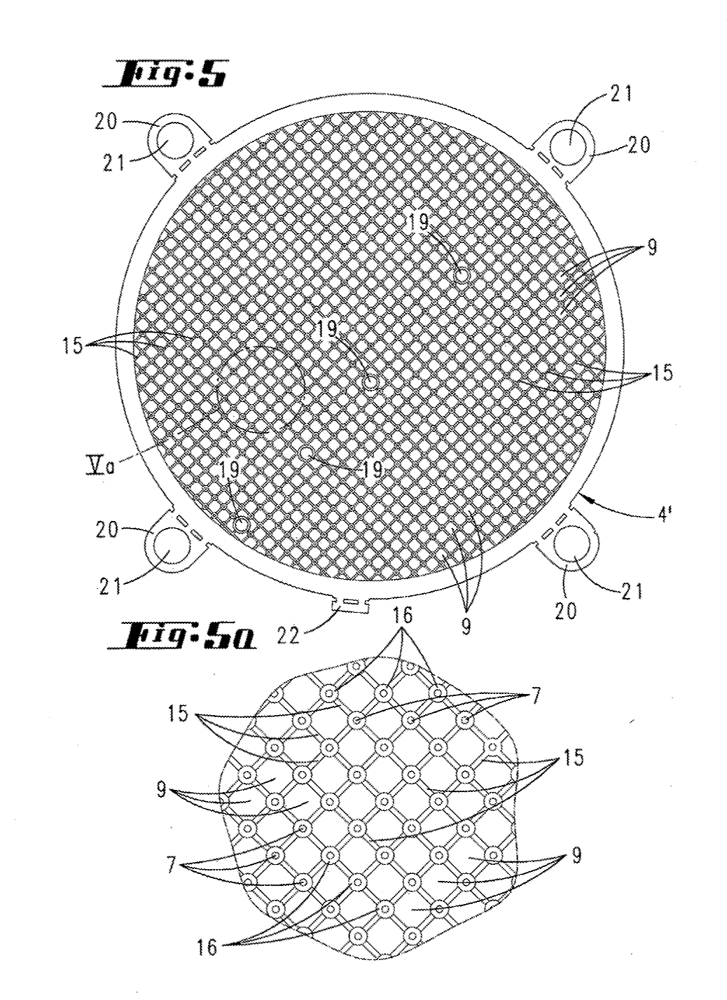

FIG. 5 shows the plan view of a second disk 4′, forming the zone B;

FIG. 5a shows an enlarged detail from the grid structure of the disk according to FIG. 5;

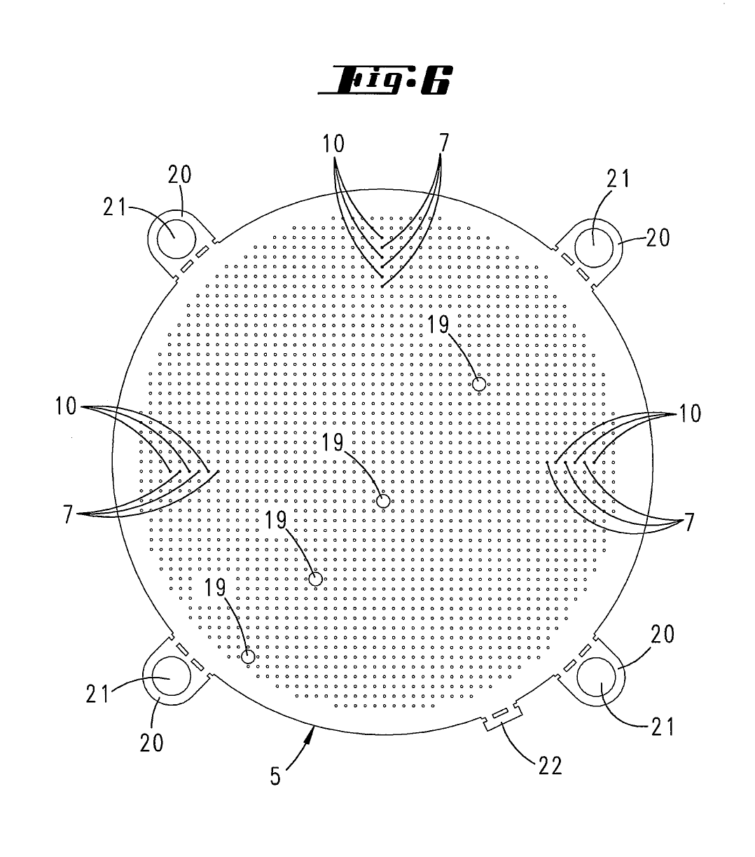

FIG. 6 shows a plan view of a disk 5 of the zones C, E;

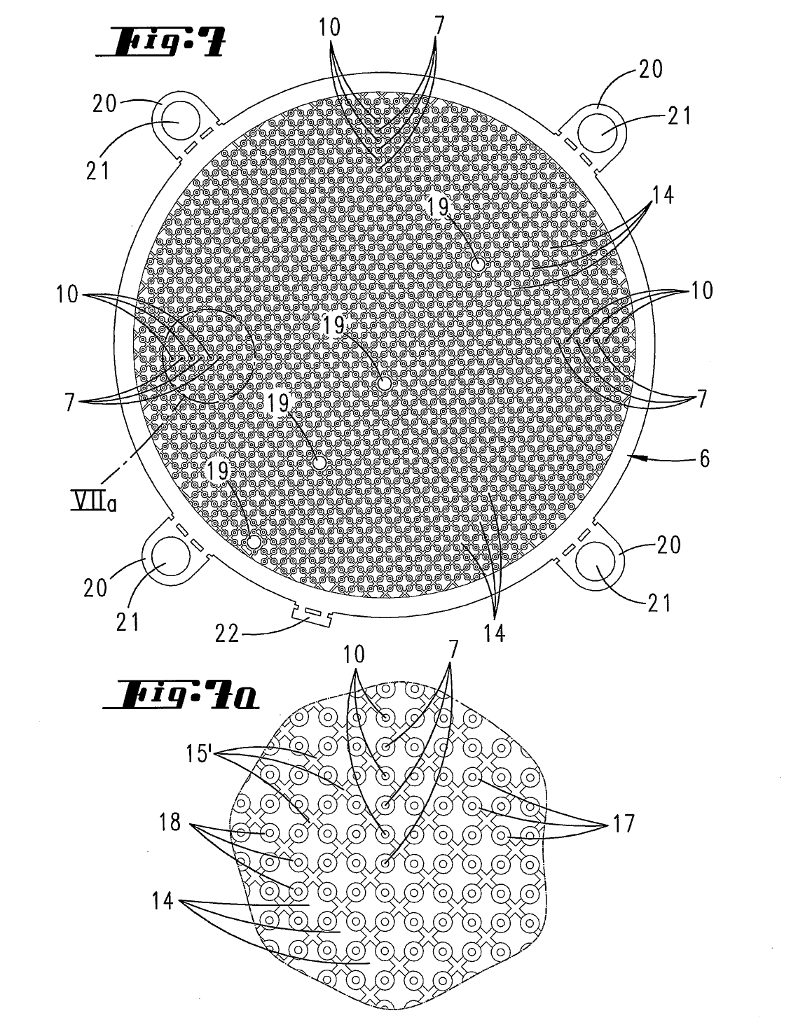

FIG. 7 shows a plan view of a disk 6 of zone D;

FIG. 7a shows an enlarged detail of the grid structure of the disk 6 represented in FIG. 7 and

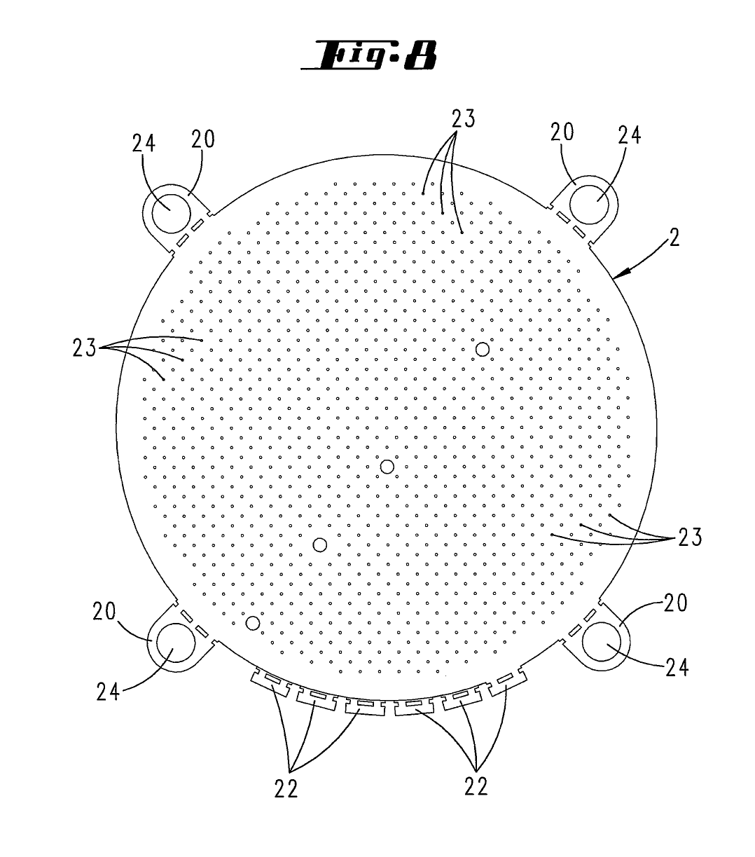

FIG. 8 shows the plan view of a disk assembly that is formed by placing the disks 3, 4, 5, 6 one above the other and is fixed and aligned by means of alignment pins 24, in the direction of the bottom 2′.

The exemplary embodiment relates to a gas distributor for a CVD reactor. The use of a gas distributor of this kind is described, in particular, in EP 0 687 749 A1. The gas distributor is part of a CVD reactor and is located vertically above a susceptor for receiving substrates to be coated. The substrates lie on a horizontal surface of the susceptor. Above the susceptor is the so-called process chamber, into which the process gases are introduced from the underside 2′ of the gas distributor 1, 2. For this purpose, the gas distributor 1, 2, which is shown inverted in FIGS. 1 and 2, has downwardly facing outlet openings 23, which are associated with the bottom 2′ of the gas distributor 1, 2 and from which a process gas or a number of process gases that are different from one another can emerge. The process gases contain constituents which form a layer to be deposited on the substrate. The process gases may contain aerosols, which merely condense on the substrates. In this case, the susceptor is cooled. The process gases may, however, also comprise reaction gases, which decompose in a heated process chamber, the decomposition products then growing on the substrate in such a way as to form a layer. As an alternative to this, the bottom surface of the gas distributor may, however, also be cooled by means of a coolant flowing through a cooling chamber 14. If, in the case of this configuration, the susceptor carrying one or more substrates is heated, the reaction gases emerging from the outlet openings flow or diffuse virtually undecomposed into the region of the surface, to decompose pyrolytically there on contact with the surface. Here, too, the layer builds up on the substrates from the decomposition products of the reaction gases. The process chamber is encapsulated in a reactor housing, which is sealed in a gas- and pressure-tight manner with respect to the surroundings. The reaction gases or the aerosols are supplied to the gas distributor from outside the reactor by means of supply lines. If different process gases or aerosols are used, a dedicated chamber in the form of a gas volume 8, 9 may be associated with each process gas or each aerosol.

FIG. 2 shows the construction of an inverted gas distributor of this kind in cross-section. The gas distributor comprises an upper part 1, which is formed by an optional, solid plate and, in the form of a recess, provides a first gas volume 8. The gas volume is closed by the broad side of a lower gas distributor part 2. This broad side of the lower gas distributor part is connected by means of a multiplicity of gas outlet channels 7, for example 10,000 to 20,000 channels, to the underside 2′ of the gas distributor. There, the gas outlet channels 7 open out into outlet openings 23.

The gas distributor 2 additionally has a second gas volume 9, which is fed by separate supply lines. This gas volume 9 is crossed by small tubes 11, which form the gas outlet channel 7 of the upper gas volume 8.

The lower gas distributor part 2 additionally has a cooling chamber 14, which is adjacent the bottom 2′ and likewise crossed by small tubes 12, 13, the small tubes 12, 13 on the one hand forming the gas outlet channel 7 of the volume 8 and on the other hand forming the gas outlet channel 10 of the gas volume 9.

The lower gas part 2 is formed by a multiplicity of structured disks 3, 4, 5, 6, which are approximately 1 mm thick, are first structured in a suitable way, then placed one above the other, and finally diffusion-welded to one another under pressure and temperature.

Altogether, the disk structure represented in FIGS. 2 and 2a comprises five differently structured disks 3, 4, 4′, 5 and 6. With these disks, the zones A, B, C, D, E that are represented in FIG. 2 are formed. The zone A is formed by a multiplicity of disks 3, which are represented in FIG. 3. A circular disk is in question here, which has a multiplicity of uniformly disposed openings 7 that have a diameter of between 0.4 mm and 1 mm. The surface density of these gas outlet channels 7 may be between 10 and 20 per cm². The openings may be drilled. However, the openings are preferably etched. For this purpose, the entire broad side face of the disk 3 is coated with a photoresist. Exposure takes place by means of a mask, which corresponds to the structure of the openings. Subsequently, the non-exposed or exposed photoresist is removed and the openings are etched.

FIGS. 4, 4a show the plan view of a disk 4 of the zone B. The disk has a solid, continuous periphery and, within the periphery, annular disks 16 connected to one another by webs 15. The annular disks 16 have a central opening, which is associated with the gas outlet channel 7. In the case of the disk 4 that is associated with zone B and is represented in FIGS. 4, 4a, the annular disks 16 are located at the web midpoint, the webs 15 crossing one another. It can be seen from FIG. 4b that the webs 15 have a material thickness that is reduced in comparison with the annular disks 16.

FIGS. 5, 5b show the plan view of a variant of a disk 4′ of the zone B, which may be disposed in alternation with a disk 4. In the case of this variant, the annular disks 16 lie on the crossing points of the crossing webs 15. The webs 15 of the disk 4′ run diagonally in relation to the webs of the disk 4. Here, too, the webs 15 have a reduced material thickness.

In the same way as the disk 3, or the disks 5 and 6 still to be explained further below, the disks 4, 4′ may be structured by etching, here too the web/annular disk structure being created photolithographically and the non-masked region of the disks subsequently being etched away anisotropically.

FIG. 6 shows a disk 5, with which the zones C and E can be formed by placing a number of disks one above the other. The disk differs from the disk 3 substantially only by having twice the number of openings. Here, the gas output channels 7 associated with the gas volume 8 and the gas output channels 10 associated with the gas volume 9 lie next to one another.

FIGS. 7, 7a show a disk 5 that is associated with the zone D and has a similar construction to the disks 4, 4′ already discussed above. Here, however, there is twice the number of annular disks 17, 18, since they form the small tubes of both outlet channels 7, 10. Here, the annular disks 17 of the gas outlet channels 10 lie at the crossing points of crossing webs 15′ and the annular disks 18, which form the gas outlet channels 7, lie at the web midpoint of the webs 15′. Here, too, the webs 15′ have a reduced material thickness.

The inter-web zones between the webs 15, 15′ form the volumes, the intermediate space between the webs 15 forming a gas volume 9 and the intermediate space between the webs 15′ forming a cooling water chamber 14. Because of the reduced material thickness of the webs 15, 15′, the individual inter-web spaces are flow-connected to one another.

The disks 3, 4, 4′, 5 and 6 respectively provide centering lugs 20 protruding from their periphery and disposed in uniform angular distribution. These centering lugs 20 are connected to the periphery of the disk 3, 4, 4′, 5, 6 by perforated webs.

An alignment device is provided, providing four alignment pins 24, which run parallel to one another and the diameter of which corresponds to the inside diameter of the alignment openings 21.

FIG. 8 shows a stack of disks placed one above the other, the respective alignment lugs 20 being fitted over the alignment pins 24.

Each disk 3, 4, 4′, 5 and 6 associated with the zones A, B, C, D and E additionally has at its periphery an identification tag 26, on which there is an identification, in order that the plates cannot be mixed up. To avoid mixups, the identification tags 22 of the disks associated with the different zones A, B, C, D, E are also provided at different angular positions.

When the plates have been placed one above the other to form the stack represented in FIG. 8, the broad side faces of adjacent plates are touching. This stack of plates is then subjected to pressure in a furnace. The broad side faces of the disks 3, 4, 4′, 5, 6 are thereby pressed against one another with approximately 1.5 MPa. At the same time, the stack of disks is heated up to a temperature which lies somewhat below the melting temperature of the metal from which the disks are produced. A preferred temperature is 1100° C. With these process parameters, the stack of plates is treated in a vacuum or in a protective gas atmosphere until the broad side portions of the individual disks 3, 4, 4′, 5, and 6 that are lying one above the other have intimately bonded to one another, so as to produce a solid structured monolith, which forms the lower gas distributor part 2. The treatment may last for approximately 4 hours.

In a variant of the invention, it is provided that the treatment temperature during the treatment is increased by 50°. The treatment temperature may lie in a window between 1000 and 1200° C.

The connection of the lower gas distributor part 2 to the upper gas distributor part 1 may take place by conventional welding.

In a variant, not illustrated, it may be provided that the upper gas distributor part 1 is also formed by a part of a wall of a reactor housing, as shown for example by FIG. 2 of EP 0 687 749 A1. In addition, it is also possible to produce the gas distributor according to the invention without a solid upper part 1.

All features disclosed are (in themselves) pertinent to the invention. The disclosure content of the associated/accompanying priority documents (copy of the prior patent application) is also hereby incorporated in full in the disclosure of the application, including for the purpose of incorporating features of these documents in claims of the present application.

1. A gas distributor (1, 2) for a CVD reactor with two or more chambers (8, 9, 14), into each of which 5 supply lines open out, at least one of the chambers (8, 9) defining a gas volume and being connected to gas outlet openings (23) associated with the bottom (2′) of the gas distributor (1, 2) by means of a multiplicity of small tubes (11, 12, 13) crossing 10 at least one other chamber (9, 14), characterized in that, at least in the region of the small tubes (11, 12, 13), the gas distributor (1, 2) comprises a multiplicity of structured disks (3, 4, 4′, 5, 6) lying one above the other, which diffusion-welded to one another by pressure and temperature, the small tubes (11, 12, 13) being formed by a multiplicity of annular disks (16, 17, 18), lying congruently one above the other.

2. A gas distributor according to claim 1, characterized in that a multiplicity of the disks (4, 4′, 6) consist of stainless steel and the annular disks (16, 17, 18) are connected to peripheries of the chambers (9,14) or to one another by way of webs (15, 15′).

3. A gas distributer according to claim 2, characterized in that the webs (15, 15′) have a smaller material thickness than the disks (3, 4, 4′, 5, 6).

4. A gas distributor according to claim 2, characterized in that the webs (15, 15′) of disks (4, 4′, 6) connected to one another define gas-permeable walls.

5. A gas distributor according to claim 1, characterized by a material thickness of the disks (3, 4, 4′, 5, 6) of from 0.3 mm to 1 mm.

6. A gas distributor according to claim 1, characterized by an inside diameter of the small tubes (11, 12, 13) of from 0.4 mm to 1 mm.

7. A gas distributor according to claim 1, characterized by a surface density of the small tubes (11, 12, 13) of from 10 to 20 per cm² or of greater than 20 per cm².

8. A gas distributor according to claim 1, characterized by a diameter of the gas distributor of at least 180 mm, at least 380 mm, at least 500 mm, or at least 700 mm.

9. A gas distributor according to claim 1, characterized by at least two gas volumes (8, 9), which are respectively connected to a bottom (2′) of the gas distributer by at least some of the small tubes (12, 13), which pass through a cooling chamber (14).

10. A gas distributer according claim 9, characterized in that the cooling chamber (14) and the at least two gas volumes are arranged one above the other.

11. A gas distributor according to claim 1, characterized in that plates forming at least one of the chambers (9) alternate with one another such that plates on which the annular disks (16) lie at the web midpoint of crossing webs (15) alternate with plates on which the annular disks (16) lie on the crossing points of crossing webs (15).

12. A gas distributor according claim 1, characterized in that the disks (3, 4, 4′, 5, 6) have removable laterally protruding alignment lugs (20), each of which has an alignment opening (21), the alignment openings (21) being placed over alignment pins (24) of an assembly aid when the disks (3, 4, 4′, 5, 6) are placed one over the other.

13. A gas distributor according to claim 12, characterized in that the alignment lugs (20) are removably connected to the disks (3, 4, 4′, 5, 6), by a perforated location being formed.

14. A gas distributor according to claim 1, characterized by identification tags (22) that are associated with the disks (3, 4, 4′, 5, 6) and can be removed after the diffusion welding of the disks (3, 4, 4′, 5, 6).

15. A method for producing a gas distributor, comprising:
producing structured disks (3, 4, 4′, 5, 6) from metal, in particular stainless steel, a multiplicity of disks (4, 4′, 6) providing annular disks (16, 17, 18) that are connected to one another by way of webs (15, 15′) and a further multiplicity of disks (3, 5) defining holes (7, 10) corresponding to the openings in the annular disks (16, 17, 18);
placing the disks (3, 4, 4′, 5, 6) one above the other in such a way that the annular disks (16, 17, 18) make up small tubes (10, 12, 13), which connect at least one chamber forming a gas volume (8, 9) to gas outlet openings (23) associated with the bottom (2′) of the gas distributor (2) and cross another chamber (9, 14), the floor and ceiling of a chamber (9, 14) that is formed by disks (4, 6) lying on above the other respectively being formed by the broad face of disks merely having bores;
diffusion-welding the disks (3, 4, 4′, 5, 6) that lie one above the other by applying pressure and temperature.

16. A method according to claim 15 or in particular according thereto, characterized in that the disks (3, 4, 4′, 5, 6) are produced from sheet metal, to which a mask corresponding to the layout of the webs (15, 15′) and the annular disks (16, 17, 18) is applied and subsequently the interspaces in the web layout are etched free.

17. A method according to claim 15 or 16 or in particular according thereto, characterized by the material thickness of the plate being reduced in the region of the webs (15, 15′) by etching.

18. A method according to claim 17, characterized by photolithographic masking.

19. A method according to claim 18, characterized by the structured disks (3, 4, 4′, 5, 6) having laterally protruding alignment lugs (20) with alignment openings (21), which in a pre-mounted state of the disks (3, 4, 4′, 5, 6) lying one above the other are passed through by alignment pins (24) of an alignment device.
